(19) United States
(12) Patent Application Publication
(10) Pub. No.: US 2026/0028743 A1
(43) Pub. Date: Jan. 29, 2026

(54) USE OF FREEZE DRYING TO MANUFACTURE A DOPANT FOR SEMICONDUCTOR INGOT GROWTH PROCESSES

(71) Applicant: GlobalWafers Co., Ltd., Hsinchu (TW)

(72) Inventors: Richard J. Phillips, St. Peters, MO (US); Carissima Hudson, St. Charles, MO (US); Alexis Grabbe, St. Charles, MO (US); YoungGil Jeong, Frisco, TX (US)

(21) Appl. No.: 19/283,653

(22) Filed: Jul. 29, 2025

Related U.S. Application Data
(60) Provisional application No. 63/676,532, filed on Jul. 29, 2024.

(51) Int. Cl. C30B 15/04; B01J 2/06; C30B 29/06

(52) U.S. Cl. CPC C30B 15/04; B01J 2/06; C30B 29/06

(57) ABSTRACT

Methods for growing a single crystal ingot using a freeze dried dopant include adding semiconductor material to a crucible of an ingot puller, heating the semiconductor material to form a melt, adding a freeze dried dopant to the melt, and pulling a single crystal ingot from the melt. A doping concentration of the single crystal ingot is controlled using the freeze dried dopant.

### CROSS-REFERENCE TO RELATED APPLICATIONS

This application claims the benefit of U.S. Provisional Patent Application Number 63/676,532, filed Jul. 29, 2024, the entire contents of which are incorporated herein by reference.

### FIELD

The field of the disclosure relates to growth processes for single crystal silicon and, more particularly, to use of freeze drying to manufacture a dopant for use in the growth of single crystal silicon.

### BACKGROUND

Single crystal silicon, which is the starting material for most processes for the fabrication of many electronic components such as semiconductor devices and solar cells, is commonly prepared by Czochralski (CZ) growth methods. In these methods, a polycrystalline source material, such as polycrystalline silicon (“polysilicon”), in the form of solid feedstock material is charged to a quartz crucible and melted, a single seed crystal is brought into contact with the molten silicon or melt, and a single crystal silicon ingot is grown by slow extraction.

CZ crystal growth generally requires crystals grown with precise control over certain parameters, such as impurities, lifetime, resistivity, oxygen, and point defectivity. Additionally, large scale crystal growth (e.g., 300 millimeter diameter ingots and larger) with large charge sizes are more commonly used to meet economic challenges. As scaling becomes larger, issues with variability and repeatability become increasingly important, in addition to meeting increasingly tighter resistivity requirements.

During ingot growth, dopants can be added to the melt to alter the properties and characteristics of the silicon material. For example, in order to achieve a target resistivity for the final wafer product, the ingot crystal can be doped with elements such as phosphorous, boron, etc. If a reliable method of delivering a precise amount of dopant is not used, the final crystal will typically fall outside of the desired specification range. Because there is segregation of electroactive elements, such as boron and phosphorous, the resistivity of the crystal typically decreases along the length of the crystal as crystal is grown and the crystal length increases. Further, segregation coefficients for boron and phosphorous are different, so the presence of both elements will cause further deviation of the resistivity from a desired target. This segregation makes growing sufficiently long crystals within customer specification windows more difficult without the need to section out lengths of crystal that fall outside of the specification range.

A need exists for systems and methods that enable controlled addition of dopant to a silicon melt to achieve controlled and precise impurity levels in the silicon ingot grown and to address increasingly tighter resistivity requirements in an efficient, reliable, cost-effective, and repeatable manner.

This section is intended to introduce the reader to various aspects of art that may be related to various aspects of the disclosure, which are described and/or claimed below. This discussion is believed to be helpful in providing the reader with background information to facilitate a better understanding of the various aspects of the present disclosure. Accordingly, it should be understood that these statements are to be read in this light, and not as admissions of prior art.

### SUMMARY

In one aspect, a method for growing a single crystal ingot includes adding semiconductor material to a crucible of an ingot puller, heating the semiconductor material to form a melt, adding a freeze dried dopant to the melt, and pulling a single crystal ingot from the melt. A doping concentration of the single crystal ingot is controlled using the freeze dried dopant.

In another aspect, a method of making a dopant for use in doping or co-doping a single crystal ingot includes mixing an aqueous precursor mixture comprising an electrically active dopant, forming one or more liquid droplets from the aqueous precursor mixture, freezing each of the one or more liquid droplets of the aqueous precursor mixture to form one or more solidified droplets of the aqueous precursor mixture, and removing water from each of the one or more solidified droplets by sublimation to form one or more freeze dried dopant granules.

Various refinements exist of the features noted in relation to the above-mentioned aspects of the present disclosure. Further features may also be incorporated in the above-mentioned aspects of the present disclosure as well. These refinements and additional features may exist individually or in any combination. For instance, various features discussed below in relation to any of the illustrated embodiments of the present disclosure may be incorporated into any of the above-described aspects of the present disclosure, alone or in any combination.

### BRIEF DESCRIPTION OF THE DRAWINGS

FIG. 1 is a schematic cross-section side view of an ingot pulling apparatus or ingot puller for forming a single crystal silicon ingot.

FIG. 2A is a plot depicting calculated resistivity trends as a function of crystal ingot length resulting from a doping operation.

FIG. 2B is a plot depicting the calculated net resulting resistivity drift for variations in the dopant added in the doping operation depicted in FIG. 2A.

FIG. 3 depicts a flow chart of an example method of making a dopant for use in doping or a co-doping a single crystal ingot of semiconductor material.

FIG. 4 is a pressure-temperature diagram of water illustrating example temperature and pressure treatment protocols for sublimation and evaporation.

FIG. 5 is a schematic cross-section side view of the ingot pulling apparatus of FIG. 1 including an example dopant feeding system for introducing a freeze dried dopant into a melt of semiconductor material.

Corresponding reference characters indicate corresponding parts throughout the drawings.

### DETAILED DESCRIPTION

Embodiments of the present disclosure relate to growth of single crystal semiconductor (e.g., silicon) ingots using a Czochralski (CZ) growth process, in which the ingot is doped or counter-doped using an electrically active element (e.g., phosphorus or boron) that alters a characteristic (e.g., resistivity) of the ingot. In this disclosure, dopants used to dope or counter-dope a silicon melt (e.g., before and/or during ingot growth) are manufactured by freeze drying. The use of the freeze dried dopant enables improved control over and better precision of the dopant addition and impurity levels in the ingot, which in turn enables addressing and meeting increasingly tightened requirements of ingot characteristics (e.g., resistivity).

In embodiments, a liquid precursor is freeze dried to manufacture the dopant which can be used as a dopant in the CZ growth of semiconductor (e.g., silicon) crystals. The liquid precursor is aqueous based and is doped with, for example, boron, phosphorus, or another suitable element which is electrically active in the semiconductor material (e.g., silicon) and has solubility or dispersibility in water. In some embodiments, the dopant is shaped in the form of spherical or essentially spherical granules or pellets of a controlled size (i.e., spheroidal). In this regard, the spheroidal granules, after freeze drying and heat treatment to stabilize the strength of the shape, can be used in CZ ingot growth processes, which require tight resistivity control in crystals which are counter doped in-situ during the crystal growth.

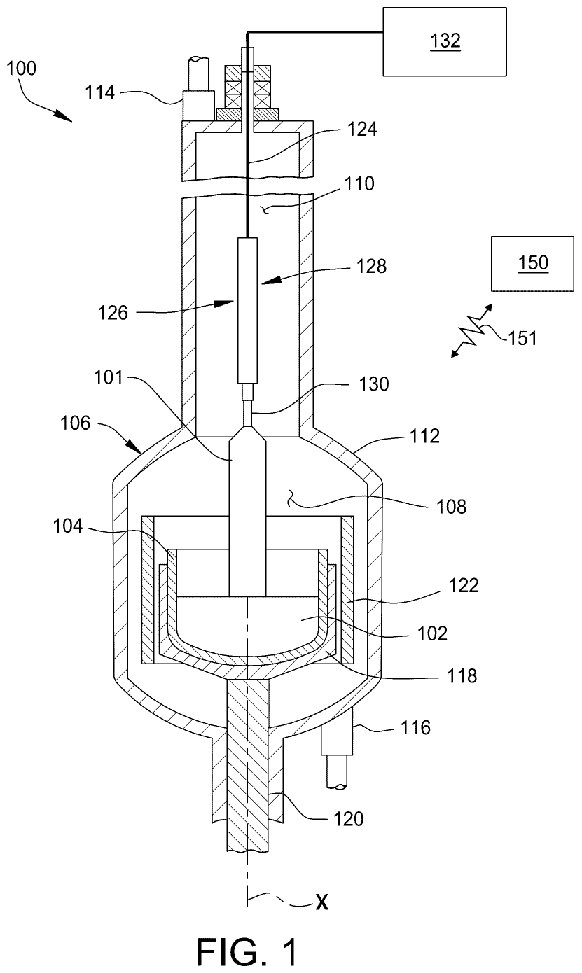

Referring to FIG. 1, an ingot pulling apparatus or ingot puller is shown schematically and is indicated generally at 100. The ingot puller 100 is used to produce single crystal (i.e., monocrystalline) ingots of semiconductor or solar-grade material such as, for example, single crystal silicon ingots. Although the ingot puller 100 is described herein primarily with reference to silicon and single crystal silicon ingots, it is understood that the ingot puller 100 is suitable for use with other types of semiconductor materials, and may be used to produce single crystal semiconductor ingots other than single crystal silicon ingots. In some embodiments, the ingot is grown by the so-called Czochralski (CZ) process in which the ingot is withdrawn from a melt 102 of silicon or other semiconductor material held within a crucible 104 of the crystal puller 100. In some embodiments, the ingot is grown by a batch CZ process in which polycrystalline silicon is charged to the crucible 104 in an amount sufficient to grow one ingot, such that the crucible 104 is essentially depleted of silicon melt 102 after the growth of the one ingot. In other embodiments, the ingot is grown by a continuous CZ (CCZ) process in which polycrystalline silicon is continually or periodically added to crucible 104 to replenish silicon melt 102 during the growth process. The CCZ process facilitates growth of multiple ingots pulled from a single melt 102. Embodiments of the subject matter described herein are not limited to a particular crystal growth process, however.

The ingot puller 100 includes a housing 106 that defines a crystal growth chamber 108 and a pull chamber 110 having a smaller transverse dimension than the growth chamber 108. The growth chamber 108 has a generally dome shaped upper wall 112 transitioning from the growth chamber 108 to the narrowed pull chamber 110. The ingot puller 100 includes an inlet port 114 and an outlet port 116 which may be used to introduce and remove a process gas to and from the ingot puller 100 during crystal growth.

The crucible 104 is positioned within the growth chamber 108 and contains the silicon melt 102 from which a single crystal silicon ingot 101 is drawn. The crucible 104 may be made of quartz or fused silica, which has a high melting point and thermal stability and is generally non-reactive with molten silicon in the melt 102. It should be understood that the crucible 104 may be made from other materials in addition to quartz without departing from the scope of the present disclosure. For example, the quartz crucible 104 may be made from a composite material that includes silica and an additional material, for example, silicon nitride or silicon carbide.

The silicon melt 102 is obtained by melting polycrystalline silicon charged to the crucible 104. In continuous systems, a feed system (not shown) is used for feeding solid feedstock material into the crucible assembly 104 and/or the melt 102. The crucible 104 is positioned within and supported by a susceptor 118 that is in turn supported by a rotatable shaft 120. Susceptor 118 and rotatable shaft 120 facilitate rotation of the crucible 104 about a central longitudinal axis X of the ingot puller 100.

A heating system 122 (e.g., one or more an electrical resistance heaters) surrounds the susceptor 118 and crucible 104 and supplies heat by radiation to the susceptor 118 and crucible 104 for melting the silicon charge to produce the melt 102 and/or maintaining the melt 102 in a molten state. The heater or heating system 122 may also extend below the susceptor 118 and crucible 104 (e.g., with additional, separate heaters). The heating system 122 is controlled by a control system 150 (e.g., via wired or wireless communication 151) so that the temperature of the melt 102 is precisely controlled throughout the pulling process. For example, the controller 150 may control electric current provided to the heating system 122 to control the amount of thermal energy supplied by the heating system 122. The controller 150 may control the heating system 122 so that the temperature of the melt 102 is maintained above the melting temperature of silicon (e.g., about 1412° C.). For example, the melt 102 may be heated to a temperature of at least about 1425° C., at least about 1450° C. or even at least about 1500° C. Insulation (not shown) surrounding the heating system 122 may reduce the amount of heat lost through the housing 106. The ingot puller 100 may also include a heat shield assembly (not shown) above the surface of melt 102 for shielding the ingot from the heat of the crucible 104 to increase the axial temperature gradient at the solid-melt interface.

A pulling mechanism 132 is attached to a pull wire 124 that extends down from the pulling mechanism. The pulling mechanism 132 is capable of raising and lowering the pull wire 124 and rotating the pull wire 124. The ingot puller 100 may have a pull shaft rather than a wire, depending upon the type of puller. The pull wire 124 terminates in a pulling assembly 126 that includes a seed crystal chuck 128 which holds a seed crystal 130 used to grow the silicon ingot. In growing the ingot, the pulling mechanism 132 lowers the seed crystal 130 until it contacts the surface of the silicon melt 102. Once the seed crystal 130 begins to melt, the pulling mechanism 132 slowly raises the seed crystal up through the growth chamber 108 and pull chamber 110 to grow the single crystal ingot. The speed at which the pulling mechanism 132 rotates the seed crystal 130 and the speed at which the pulling mechanism 132 raises the seed crystal (i.e., the pull rate v) are controlled by the ingot puller control system 150. As the seed crystal 130 is slowly raised from the melt 102, silicon atoms from the melt 102 align themselves with and attach to the seed crystal 130 to form an ingot.

A process gas (e.g., argon) is introduced through the inlet port 114 into the growth chamber 108 and pull chamber 110 and is withdrawn through the outlet port 116. The process gas creates an atmosphere within the housing. The melt and atmosphere form a melt-gas interface. The outlet port 116 is in fluid communication with an exhaust system (not shown) of the ingot puller.

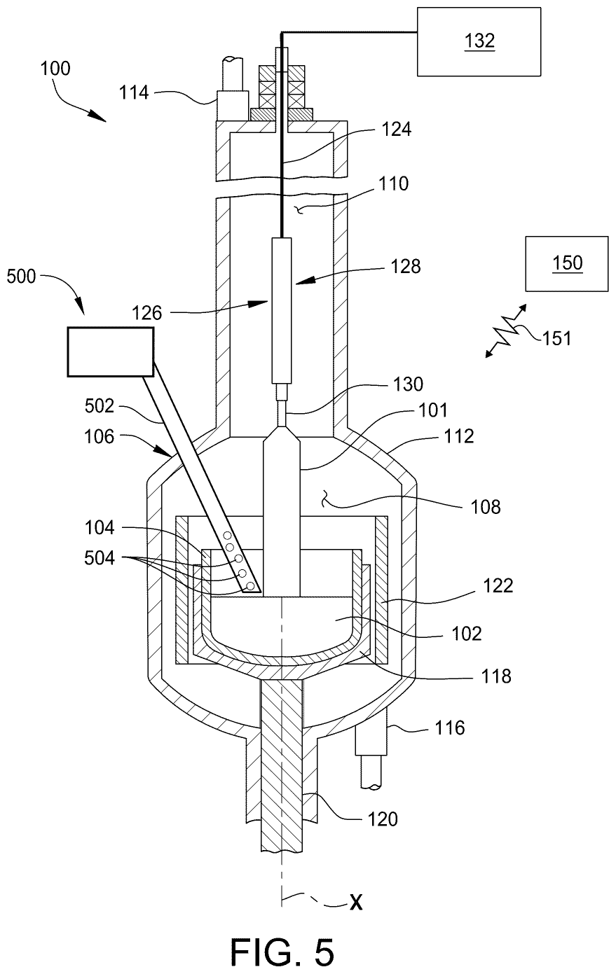

In at least some ingot growth processes, the melt 102 is charged with a desired amount of dopant prior to and/or during growth of the crystal ingot to achieve a desired or target resistivity for wafers sliced from the resulting ingot. The dopant can be an n-type dopant (e.g., phosphorus) and/or a p-type dopant (e.g., boron). In some embodiments, the n-type dopant is added to compensate for p-type impurities (e.g., boron) in the melt 102. By doping the melt 102, such as by compensating for p-type dopant impurities in the melt, the resistivity of the resulting ingot may be controlled to a targeted resistivity. The dopant may be added to the melt 102 using known techniques, such as a dopant feed tube (shown in FIG. 5). Other examples of suitable dopants include, for example and without limitation, arsenic, gallium, antimony, bismuth, and any other elemental dopant suitable for use in CZ doping operations.

Dopants can be introduced into a silicon melt in many forms. In one approach, an alloyed rod of silicon is inserted at specific times or to a specific depth in order to introduce counter dopant into the melt. This approach requires a mechanical device to introduce the rod during the crystal growth. The manufacture of such a rod can also potentially have intrinsic segregation issues at least radially if it is produced from a previously grown crystal. In another approach, a gas precursor, such as di-borane, can be used in silicon doping or counter-doping operations. Such gas doping is common, for example, to provide for a boron-controlled ambient over the meniscus (i.e., the curve between the melt-solid interface and the surface of the melt) in doping float zone crystals. However, use of such gaseous doping systems can be costly to install and operate, and is less reliable when used in CZ growth processes because the surface of the melt is larger than the liquid meniscus area in a float zone operation. In another approach, doped silicon wafer chips are introduced into the melt at specific times during crystal growth. Such silicon chips are typically sectioned from a wafer, which is subject to a typical radial resistivity variation on the order of 10% because of the crystal used to grow the original wafer. Thus, it would be expected that this resistivity variation will result in variability in the counter dopant, which causes a difference from an expected target resistivity profile down the length of the crystal. For a +/−10% resistivity variation from a nominal value for the dopant, this can translate to additional deviation from target or expected resistivity values. Additionally, use of silicon alloy as a dopant will often have both boron and phosphorous present in the crystal structure because of the original crystal from which it is derived. Determining the precise amount or concentration of boron and dopant in this material can be difficult because resistivity measurements cannot separate the concentrations of each dopant material, since the electrical resistivity measured represents the excess of majority carriers in the dopant. Thus, precisely determining the amount or concentrations of different dopants being added can be difficult when using silicon alloys in doping or co-doping procedures.

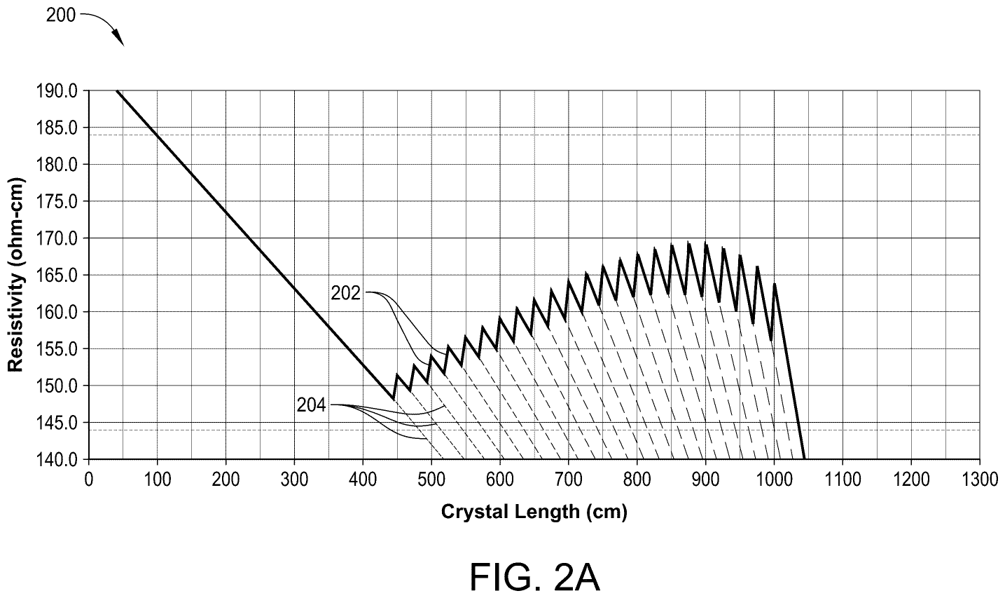

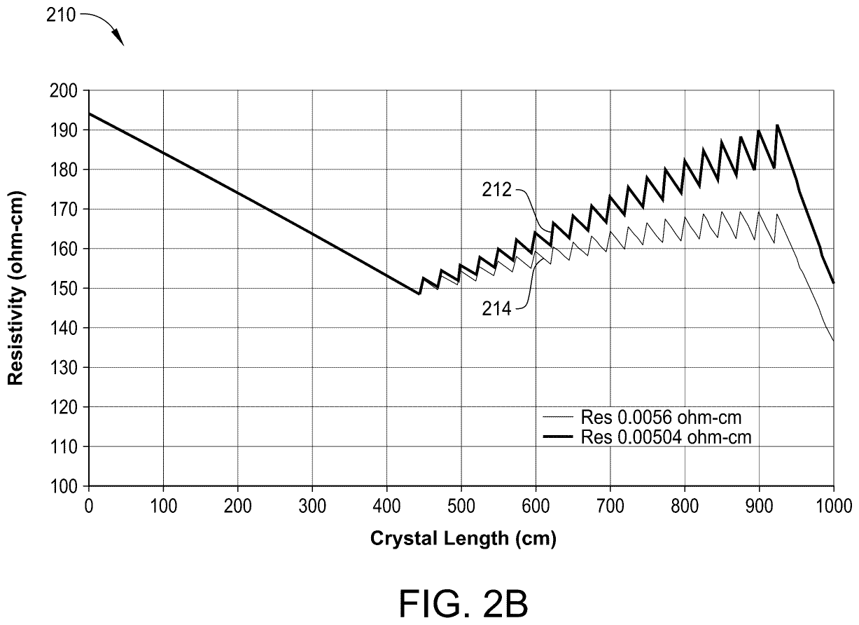

Referring to FIG. 2A, a plot 200 of calculated resistivity as a function of crystal ingot length is depicted for an example ingot growth process having a selected starting seed end resistivity. In this n-type example, boron-silicon dopant alloy was used with additions of 10 milligrams, with a nominal dopant resistivity of 5.6 milliohm-cm. Each upward increase 202 in the plot represents a dopant addition to the melt from which the crystal was grown. The sweeping downward trends 204 are the resulting resistivity if the dopant additions were stopped at that length in the crystal. In this example, it can be seen that each dopant addition 202 causes the resistivity to increase at that segment in the crystal. In this example, 23 dopant additions were made.

FIG. 2B is a comparative plot 210 depicting the calculated net resulting resistivity drift for variations in the dopant added in the doping operation depicted in FIG. 2A. In particular, FIG. 2B includes a first plot line 212 for the calculated resulting resistivity of the doping operation depicted in FIG. 2A, and a second plot line 214 depicting the calculated resulting resistivity for the same doping operation using a boron-silicon dopant alloy with a 10% deviation below the nominal dopant resistivity (5.6 milliohm-cm). That is, the second plot line 214 depicts the calculated resulting resistivity for a doping operation in which 23 dopant additions of boron-silicon dopant alloy were made, with additions of 10 milligrams, and a nominal dopant resistivity of 5.04 milliohm-cm (i.e., 10% below the target resistivity of 5.6. milliohm-cm). As shown in FIG. 2B, the resistivity profile of the crystal ingots can vary quite significantly as a result of variations in the resistivity of the added dopants. For example, a deviation of 10% below the target dopant resistivity results in a 6.7% average deviation from the target resistivity in the crystal over the 23 doping additions.

Use of freeze drying to form dopants in accordance with the present disclosure can facilitate reducing the deviation from target resistivity described above with reference to FIG. 2. For example, by using liquid aqueous precursor solutions or mixtures and shape forming with freeze drying, in accordance with the present disclosure, the minority carrier impurity carryover can be eliminated. Further, by mixing a liquid precursor and using dilution techniques, better control of the concentration of the electrically active majority carrier dopant element can be achieved, and the variability introduced from radial resistivity variation in the chip type dopant can be avoided.

Embodiments of the present disclosure involve the use of freeze drying to avoid any segregation during processing, and to manufacture a larger particle sizes (millimeters) which can be fed through a dopant feed tube at a specific time to dope or counter-dope a silicon melt. The larger particle size provides for sufficient mass to avoid competition with inert gas (e.g., argon) flow in the CZ ingot puller apparatus such that delivery into the melt can be accomplished. Further, since the concentration of compensating dopant can be very small, the aqueous mixture can be diluted to meet the required masses of electroactive dopant to achieve the appropriate counter-doped resistivity. Since the soluble salts from which the mixture is formulated are not themselves necessarily being derived via process associated with segregation, the dopant mass per droplet can be controlled more tightly, and the presence of other electrically active elements may not necessarily be present. Thus, the counter dopant can be more refined in terms of the actual mass of desired electrically active dopant being delivered. This provides improved dopant characteristics as compared to other silicon-based solid dopants, for example, which typically have both boron and phosphorous present as a result of segregation resulting from their manufacturing processes. Additionally, methods of dopant preparation in accordance with the present disclosure provide the advantage of nearly identical preparation procedures—i.e., mixing of constituents into a liquid-aging and storing prior to use. These methods are relatively cheap compared to other methods of preparing dopants, such as growing a heavily doped silicon ingot as a source, analyzing it, dicing, and cleaning it to make dopant chips, for example.

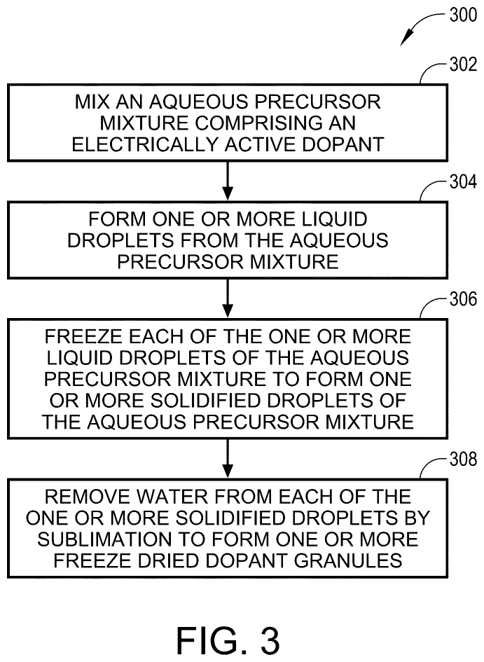

FIG. 3 is a flow diagram of an example method 300 of making a dopant for use in doping or a co-doping a single crystal ingot of semiconductor material. For example, the method 300 depicted and described with reference to FIG. 3 can be used to dope or co-dope a melt (e.g., melt 102) of semiconductor material (e.g., silicon) prior to and/or during growth of a single crystal ingot (e.g., ingot 101).

The example method 300 includes mixing 302 an aqueous precursor mixture comprising an electrically active dopant, forming 304 one or more liquid droplets from the aqueous precursor mixture, freezing 306 each of the one or more liquid droplets of the aqueous precursor mixture to form one or more solidified droplets of the aqueous precursor mixture, and removing 308 water from each of the one or more solidified droplets by sublimation to form a corresponding number of one or more freeze dried dopant granules.

The aqueous precursor mixture can include, for example and without limitation, homogeneous mixtures (e.g., solutions), heterogenous mixtures (e.g., colloidal suspensions), and combinations thereof. In some embodiments, for example, the aqueous precursor mixture includes a homogeneous mixture or solution with an electrically active dopant solute molecularly or ionically dispersed in a solvent (e.g., water). Additionally or alternatively, the aqueous precursor mixture can include one or more heterogenous mixtures, such as colloidal silica (e.g., as a carrier medium for the electrically active dopant) or a colloidal suspension of the electrically active dopant in water or another suitable medium.

The electrically active dopant can be present in the aqueous precursor mixture, for example, in the form of a liquid dopant solution (e.g., where the electrically active dopant is dissolved in water) or as a colloidal dopant suspension (e.g., where the electrically active dopant is dispersed in water). The electrically active dopant can include, for example and without limitation, boron, phosphorous, arsenic, antimony, germanium (e.g., to increase lattice strain), nitrogen (e.g., to control oxygen precipitation), and combinations thereof. In principle, any element may be used as the electrically active dopant within the practical limits constrained by relative evaporation rates and segregation coefficients. Examples of suitable solvents (or mediums, in the case of colloidal suspensions) include, for example and without limitation, water. Other solvents might be used (e.g., hydrogen silsesquioxane(s)), provided that they are benign, can dissolve the electrically active dopant, and can be evaporated or sublimated. Other suitable solvents should have a heat of vaporization comparable to water.

In some embodiments, the aqueous precursor mixture is made with a water-soluble or water dispersible dopant, such as oxides of the electrically active dopant, hydroxides of the electrically active dopant, or a colloidal suspension of the electrically active dopant in water. In some embodiments, for example, mixing 302 an aqueous precursor mixture includes dissolving the electrically active dopant in water to form a liquid dopant solution, and/or dispersing the electrically active dopant in water to form a colloidal dopant suspension. For example, where the aqueous precursor mixture is formed by dissolving the electrically active dopant in water to form a liquid dopant solution, dissolving the electrically active dopant in water can include mixing a water-soluble dopant oxide precursor or a water-soluble dopant hydroxide precursor in water. One example of a suitable water-soluble dopant oxide precursor or water-soluble dopant hydroxide precursor is boric acid. In other embodiments, for example, where the dopant is not water soluble, mixing 302 an aqueous precursor mixture can include mixing the electrically active dopant in a suitable carrier medium, such as water, to form a colloidal dopant suspension.

In addition, in some embodiments, an amount of the electrically active dopant within the aqueous precursor mixture can be diluted prior to freezing 306. In some embodiments, for example, mixing 302 an aqueous precursor mixture includes mixing an amount of the electrically active dopant in water to form a liquid dopant mixture having a first concentration of the electrically active dopant, and subsequently diluting the amount of the electrically active dopant in the liquid dopant mixture to a second concentration less than the first concentration by adding water to the liquid dopant mixture. Using dilution techniques can, for example, help to enhance control of the concentration of the electrically active majority carrier dopant element in the resulting freeze dried dopant granules. The resulting or target concentration of the electrically active dopant in the liquid precursor mixture will depend, for example, on characteristics of the target crystal and whether it needs to be lightly or heavily doped. At the same time, the resulting freeze dried dopant granule should be large enough or have sufficient mass such that it is not carried away by a process gas (e.g., argon) or does not stick to the wall of the crucible. For very small doses or concentrations, for example, the dopant may be dispersed in an aqueous mixture of high purity colloidal silica, so that the granule size is large enough for practical transport in the crystal pulling apparatus. A colloidal suspension can also have an apparent concentration of dopant in excess of the solubility limit.

The aqueous precursor mixture can also include other additives to facilitate formation of the freeze dried dopant including, for example and without limitation, binders, silica or silica gels, viscosity modifiers, and/or surfactants. In some embodiments, for example, mixing the aqueous precursor mixture includes mixing the electrically active dopant (e.g., in the form of a liquid dopant solution or a colloidal dopant suspension) with one or more of a binder, a silica or silica gel, a viscosity modifier, and/or a surfactant to form the aqueous precursor mixture. Suitable binders include, for example and without limitation, polyvinyl alcohol and polyvinyl butyral. Suitable viscosity modifiers include, for example and without limitation, colloidal silica and, more generally, water-soluble polymers, though it is preferable that the polymer not contain nitrogen, unless nitrogen is intended to be used as a dopant in the freeze dried dopant granule. Examples include, without limitation, polyvinyl alcohol, polyethylene oxide, hydroxymethyl cellulose, carboxymethyl cellulose, Xanthan gum. Suitable surfactants include, for example and without limitation, hyperdispersants, such as commercially-available hyperdispersants sold under the brand name Solsperse™.

Once the aqueous precursor mixture is formed, the aqueous precursor mixture is formed 304 into one or more liquid droplets of the aqueous precursor mixture. Any suitable method of forming droplets from the aqueous precursor mixture may be used. In some embodiments, for example, the aqueous precursor mixture is directed through an orifice to form one or more liquid droplets of the aqueous precursor mixture. In some embodiments, for example, a dripping process is used in which the aqueous precursor mixture is allowed to pass through an orifice under the force of gravity to create a plurality of liquid droplets of the aqueous precursor mixture. Any suitable freeze drying apparatus capable of injecting a liquid droplet into a partial vacuum may be used to form 304 and freeze 306 liquid droplets of the aqueous precursor mixture. For example, a drop tower which allows the droplets to free fall for a sufficient distance or time to freeze may be used in the methods of the present disclosure.

In embodiments in which the aqueous precursor mixture is directed through an orifice to form droplets, a single orifice can be used to form liquid droplets one at a time, or multiple orifices can be used to form a plurality of liquid droplets in parallel. Additionally, in such embodiments, the size of the orifice is suitably selected to produce liquid droplets of a desired size (e.g., on the order of a few millimeters), which will produce solidified droplets and resulting freeze dried dopant granules having approximately the same size. The size, shape, and materials of construction of the nozzle defining the orifice can affect the droplet size. The nozzle can suitably be constructed of hydrophobic materials to prevent the aqueous precursor mixture from sticking to the nozzle. Additionally, the apparatus used in the freeze drying process can be configured to push a liquid droplet past a valve, followed by an air bubble to force the drop out of the nozzle such that, when the valve shuts, no liquid is present within the valve. This can help prevent formation of a dried crust downstream of the valve, which may eventually clog the nozzle.

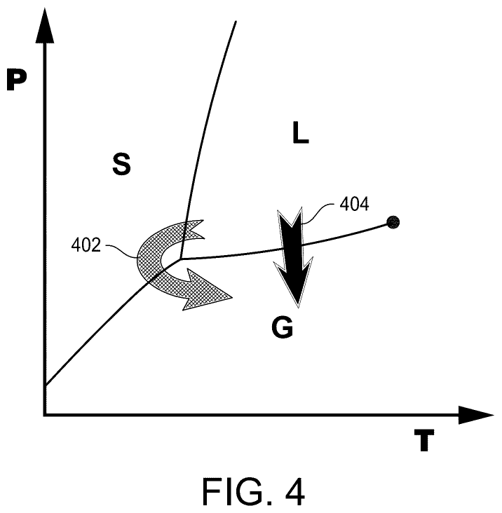

Each of the one or more liquid droplets of the aqueous precursor mixture is frozen 306 to form one or more solidified droplets (typically, a corresponding number of solidified droplets) of the aqueous precursor mixture. Any freezing method suitable for use in freeze drying can be used to freeze 306 the one or more liquid droplets of the aqueous precursor mixture. For example, the one or more liquid droplets are subjected to a sub-zero temperature at a suitable pressure for a time sufficient to freeze the liquid droplets. Suitable temperatures, pressures, and times can be readily determined by those skilled in the art with reference to appropriate phase diagrams or pressure-temperature diagrams, such as the water pressure-temperature diagram shown in FIG. 4. In some embodiments, freezing 306 the one or more liquid droplets of the aqueous precursor mixture comprises subjecting the liquid droplet to a temperature less than 0° C., less than −10° C., less than −15° C., or less than −20° C., at atmospheric or sub-atmospheric pressure for a time sufficient to freeze the liquid droplet. In some embodiments, the liquid droplets of the aqueous precursor mixture are frozen 306 by dripping the liquid droplets into a liquid nitrogen-cooled chamber, and/or by dripping the liquid droplets directly into liquid nitrogen, which has a temperature of less than 195° C. at atmospheric pressure. The pressure within such a chamber may be suitably controlled to be below atmospheric pressure or above atmospheric pressure to maintain the frozen droplets in a solidified state prior to sublimation of the frozen solvent. The solidified droplets suitably have a spherical or spheroidal shape due to the formation of the solidified droplets by freezing liquid droplets.

The specific temperature and pressure protocols would be based on product output need in terms of physical size of the output, strength, purity, etc. Commercially available freeze drying apparatus have suitable size and capacity outputs and are capable of temperature and pressure control with the above modifications to produce desired output needs within the scope of the present disclosure.

Freezing 306 the one or more liquid droplets of the aqueous precursor mixture will typically result in formation of a corresponding number of solidified droplets as the number of liquid droplets, although it is possible that the number of solidified droplets differs from the number liquid droplets formed during forming 304 of the one or more liquid droplets from the aqueous precursor mixture. For example, one more of the liquid droplets may not solidify during the freezing process or two or more of the droplets may combine into a single droplet prior to freezing.

Each of the one or more solidified droplets of the aqueous precursor mixture is subsequently subjected to a sublimation process. More specifically, and with continued reference to FIG. 3, the method 300 further includes removing 308 water from each of the one or more solidified droplets of the aqueous precursor mixture by sublimation to form a corresponding number of one or more freeze dried dopant granules.

The sublimation process is carried out at a suitable temperature and pressure to maintain the solidified droplets of the aqueous precursor mixture to the left of and below the triple point of the solvent (e.g., water), which is defined as the point on the pressure-temperature diagram (shown in FIG. 4) at which the solvent can exist as solid(S), liquid (L) and gas (G) together in equilibrium. For pressures below the triple point, for example, as the temperature of the solidified droplets are slowly raised, it is possible to transform the frozen solvent (e.g., water) within the solidified droplet to a gas through the sublimation process. This is shown by the arrow labeled 402 in FIG. 4. By contrast, evaporation involves conversion of a liquid to a gas and a different combination of temperature and pressures above the triple point, as depicted by the arrow labeled 404 in FIG. 4.

In some embodiments, for example, removing 308 water from each of the one or more solidified droplets via sublimation includes heating each of the one or more solidified droplets at a pressure less than atmospheric pressure to sublimate water present in each of the one or more solidified droplets. Suitable temperatures, pressures, and times can be readily determined by those skilled in the art with reference to appropriate phase diagrams or pressure-temperature diagrams.

In some embodiments, the method 300 further includes subjecting the freeze dried dopant granules to one or more additional subsequent heat treatments or desorption steps following the sublimation process. In some embodiments, for example, the method 300 includes subjecting each of one or more freeze dried dopant granules to a heat treatment to stabilize the strength of the shape and/or to remove organics in the binder. Such subsequent heat treatments or desorption steps can include heating the one or more freeze dried dopant granules to a temperature higher than a temperature used during the initial sublimation step.

The resulting freeze dried dopant granules formed using the method 300 can be spherical or spheroidal due to the formation of the dopant granules by solidifying liquid droplets. The term spheroidal refers to a shape that is spherical or substantially spherical and, to the extent it is not a perfect geometric sphere, possesses an overall form that approximates a sphere to a substantial degree. Dopants that are substantially spherical but include minor deviations from a perfect sphere arising, for example, from manufacturing tolerances, environmental influences, or inherent imperfections in the formation process, can still be considered spheroidal within the scope of the present disclosure, provided such deviations do not materially affect the overall spherical nature or the intended function of the dopant.

The freeze dried dopant granules have a size suitable for use in doping or co-doping a melt (e.g., melt 102) of semiconductor material (e.g., silicon) prior to and/or during growth of a single crystal ingot. In some embodiments, for example, each of the freeze dried dopant granules has a diameter within the range of 1 mm to 10 mm, within a range of 1 mm to 5 mm, within a range of 1 mm to 4 mm, within a range of 1 mm to 3 mm, or within a range of 2 mm to 3 mm. A range of 2 mm to 3 mm is particularly suitable for use with a wide range of existing dopant feeding tools. The size of the resulting freeze dried dopant granules can be selectively varied by adjusting the size of the liquid droplets formed during the step of forming 304 one or more liquid droplets from the aqueous precursor mixture. In some embodiments, for example, the size of the orifice(s) through which the aqueous precursor mixture is directed can be selected to achieve a desired size of the resulting freeze dried dopant granules.

In one example, an aqueous precursor mixture is formed by adding boron or phosphorous to water up to the solubility limit, and optionally diluting the concentration of the boron or phosphorous if needed by increasing the volume of water in the aqueous precursor mixture. This aqueous precursor mixture can be mixed with an appropriate binder to obtain adequate green strength and viscosity. In one specific example, the aqueous precursor mixture includes a dopant precursor acid in the form of boric acid, a binder (e.g., polyvinyl alcohol or polyvinyl butyral), water, viscosity modifiers (e.g., silica or a silica gel) and surfactants (e.g, Solsperse™ hyperdispersants).

The aqueous precursor mixture is then dripped through one or more orifices to form liquid droplets of a desired size, and the liquid droplets are introduced into a cold region of a freeze drying apparatus to freeze the liquid droplets at a specific pressure to form solidified droplets of the aqueous precursor mixture. After freezing, the solidified droplets are warmed or heated under reduced pressure (i.e., sub-atmospheric pressure) to sublimate water within the solidified droplets and form one or more freeze dried dopant granules. The freeze dried dopant granules can be further heated to remove remaining organics in the binder, and/or heat treated to obtain sufficient strength for handling.

In embodiments of the present disclosure, the aqueous precursor mixture is homogeneous or substantially homogenous (e.g., equally dispersed in the case of a colloidal suspension) before formation of the liquid droplet, and the process of freezing liquid droplets of the aqueous precursor mixture does not cause segregation of the dopant with the liquid droplets. Consequently, the resulting freeze dried dopant granules include an electrically active dopant that can be substantially uniformly distributed throughout the dopant granule, and the mass of dopant carried into a melt is dependent only on the size of the frozen droplets. In some instances, for example, the resulting freeze dried dopant granules will include electrical active dopant mixed or dispersed among a carrier material (e.g., colloidal silica and/or remaining polymer). In some instances, the carrier material will be the dominant or majority mass fraction of the freeze dried dopant granule. In other instances, the electrically active dopant will constitute the dominant or majority mass fraction of the freeze dried dopant granule.

Further, the freeze drying processes of the present disclosure provide considerable room to vary the concentration in the pre-frozen liquid (i.e., the aqueous precursor mixture) such that a workable droplet size can be accessed. Additionally, the freeze drying processes of the present disclosure help improve the uniformity of the amount of electrically active dopant amongst a given batch of freeze dried dopant granules. In some embodiments, for example, for a given batch of freeze dried dopant granules, where each dopant granule includes an amount of electrically active dopant, the amount of electrically active dopant within each dopant granule varies by less than 10%, less than 5%, less than 3%, less than 2%, less than 1%, less than 0.5%, or even less than 0.1%.

In an example crystal growth process in accordance with the present disclosure, freeze drying is used to avoid any segregation during processing, and to manufacture a larger particle size (e.g., on the order of millimeters) which can be fed into the melt 102 (e.g., via a dopant feed tube) at a specific time to counter-dope the melt 102. The larger particle size provides for sufficient mass to avoid competition with the process gas (e.g., argon) flow in the growth chamber 108 such that delivery into the melt 102 can be accomplished. Further, since the concentration of compensating dopant can be very small, the aqueous solution can be diluted to meet the required masses of electroactive dopant to achieve the appropriate counter-doped resistivity. Since the soluble salts from which the solution is formulated are not themselves necessarily being derived via process associated with segregation, the dopant mass per droplet can be controlled more tightly, and the presence of other electroactive elements may not necessarily be present. Thus, the counter dopant is more refined in terms of the actual mass of desired electroactive dopant being delivered.

FIG. 5 illustrates the ingot puller 100 of FIG. 1 equipped with a dopant feeding system 500 suitable for use with the freeze dried dopants disclosed herein. As shown in FIG. 5, the dopant feeding system 500 includes a dopant feed tube 502 through which freeze dried dopant granules 504 can be selectively and intermittently fed into the melt 102 to dope or counter-dope the melt 102. The dopant feeding system 500 can be used to introduce dopants into the melt 102 before and/or during growth of the single crystal ingot 101. The dopant feeding system 500 of FIG. 5 is illustrative only, and it should be understood that freeze dried dopants of the present disclosure can be introduced into a melt of semiconductor material using any other suitable dopant feeding apparatus known in the art. Examples of other suitable dopant feeding apparatus are disclosed, for example, in U.S. Patent Application Publication No. 2024/0392466, and U.S. Pat. Nos. 10,060,045; 11,499,245; 11,585,010; and 12,084,785, the entire disclosures of which are hereby incorporated by reference in their entireties.

The ingot puller 100 can be used a grow a single crystal ingot 101 using the freeze dried dopants disclosed herein. In some embodiments, for example, an example method includes adding semiconductor material to the crucible 104 and heating the semiconductor material to form the melt 102, adding a freeze dried dopant (e.g., in the form of freeze dried dopant granules 504) to the melt 102, and pulling the single crystal ingot 101 from the melt 102. A doping concentration of the single crystal ingot 101 is controlled using the freeze dried dopant, for example, by selectively adding precise amounts of the freeze dried dopant before and/or during growth of the crystal ingot 101 (e.g., at select times during ingot growth). The freeze dried dopant added to the melt 102 can be suitably formed using the freeze drying processes described herein. In the illustrated embodiment, the freeze dried dopant includes a plurality of dopant granules 504, and each dopant granule 504 includes an amount of electrically active dopant. The electrically active dopant can be uniformly distributed throughout the dopant granule 504 using the freeze drying processes of the present disclosure. Additionally, in some embodiments, the amount of electrically active dopant within each dopant granule 504 varies by less than less than 10%, less than 5%, less than 3%, less than 2%, less than 1%, less than 0.5%, or even less than 0.1% across the batch of dopant granules. That is, the amount of electrically active dopant within each dopant granule 504 can be within +/−5%, +/−2.5%, +/−1.5%, +/−1%, +/−0.5%, +/−0.25%, or +/−0.05% of one another.

As used herein, the terms “about,” “substantially,” “essentially” and “approximately” when used in conjunction with ranges of dimensions, concentrations, temperatures or other physical or chemical properties or characteristics is meant to cover variations that may exist in the upper and/or lower limits of the ranges of the properties or characteristics, including, for example, variations resulting from rounding, measurement methodology or other statistical variation.

When introducing elements of the present disclosure or the embodiment(s) thereof, the articles “a,” “an,” “the,” and “said” are intended to mean that there are one or more of the elements. The terms “comprising,” “including,” “containing,” and “having” are intended to be inclusive and mean that there may be additional elements other than the listed elements. The use of terms indicating a particular orientation (e.g., “top,” “bottom,” “side,” etc.) is for convenience of description and does not require any particular orientation of the item described.

As various changes could be made in the above constructions and methods without departing from the scope of the disclosure, it is intended that all matter contained in the above description and shown in the accompanying drawing(s) shall be interpreted as illustrative and not in a limiting sense.

What is claimed is:

1. A method for growing a single crystal ingot, the method comprising:
adding semiconductor material to a crucible of an ingot puller;
heating the semiconductor material to form a melt;
adding a freeze dried dopant to the melt; and
pulling a single crystal ingot from the melt, wherein a doping concentration of the single crystal ingot is controlled using the freeze dried dopant.

2. The method of claim 1, wherein the freeze dried dopant comprises a plurality of dopant granules, wherein each dopant granule comprises an amount of electrically active dopant, and wherein the amount of electrically active dopant within each dopant granule varies by less than 2%.

3. The method of claim 1, wherein the freeze dried dopant comprises a plurality freeze dried dopant granules each having a spheroidal shape.

4. The method of claim 1, wherein the freeze dried dopant comprises an electrically active dopant selected from the group consisting of boron, phosphorous, arsenic, and antimony.

5. The method of claim 1, further comprising forming the freeze dried dopant by:
freezing one or more liquid droplets of an aqueous mixture to form one or more solidified droplets of the aqueous mixture; and
removing water from each of the one or more solidified droplets by sublimation to form one or more freeze dried dopant granules.

6. The method of claim 5, wherein the aqueous mixture comprises an electrically active dopant selected from the group consisting of boron, phosphorous, arsenic, and antimony.

7. The method of claim 6, wherein the aqueous mixture comprises an aqueous solution comprising the electrically active dopant dissolved in water.

8. The method of claim 6, wherein the aqueous mixture comprises a colloidal suspension of the electrically active dopant in water.

9. A method of making a dopant for use in doping or co-doping a single crystal ingot, the method comprising:
mixing an aqueous precursor mixture comprising an electrically active dopant;
forming one or more liquid droplets from the aqueous precursor mixture;
freezing each of the one or more liquid droplets of the aqueous precursor mixture to form one or more solidified droplets of the aqueous precursor mixture; and
removing water from each of the one or more solidified droplets by sublimation to form one or more freeze dried dopant granules.

10. The method of claim 9, wherein the electrically active dopant is selected from the group consisting of boron, phosphorous, arsenic, and antimony.

11. The method of claim 9, wherein the freeze dried dopant granule is spherical or spheroidal.

12. The method of claim 11, wherein the freeze dried dopant granule has a diameter within the range of 1 mm to 10 mm.

13. The method of claim 12, wherein the freeze dried dopant granule has a diameter within the range of 1 mm to 4 mm.

14. The method of claim 9, wherein mixing an aqueous precursor mixture comprises at least one of:
dissolving the electrically active dopant in water to form a liquid dopant solution; and
dispersing the electrically active dopant in water to form a colloidal dopant suspension.

15. The method of claim 14, wherein dissolving the electrically active dopant in water comprises mixing a water-soluble dopant oxide precursor or a water-soluble dopant hydroxide precursor in water.

16. The method of claim 15, wherein the water-soluble dopant oxide precursor or water-soluble dopant hydroxide precursor comprises boric acid.

17. The method of claim 14, wherein mixing the aqueous precursor mixture comprises mixing the liquid dopant solution or colloidal dopant suspension with a binder, a viscosity modifier, and a surfactant.

18. The method of claim 9, wherein mixing an aqueous precursor mixture comprises mixing an amount of the electrically active dopant in water to form a liquid dopant mixture having a first concentration of the electrically active dopant; and
subsequently diluting the amount of the electrically active dopant in the liquid dopant mixture to a second concentration less than the first concentration by adding water to the liquid dopant mixture.

19. The method of claim 9, wherein forming one or more liquid droplets from the aqueous precursor mixture comprises directing the aqueous precursor mixture through an orifice to form the one or more liquid droplets.

20. The method of claim 9, wherein freezing each of the one or more liquid droplets of the aqueous precursor mixture comprises subjecting each of the one or more liquid droplets to a temperature less than 0° C. for a time sufficient to freeze the liquid droplet.

21. The method of claim 9, wherein removing water from each of the one or more solidified droplets via sublimation comprises heating each of the one or more solidified droplets at a pressure less than atmospheric pressure to sublimate water present in each of the one or more solidified droplets.

22. The method of claim 9 further comprising subjecting the freeze dried dopant granule to a heat treatment subsequent to removing water from each of the one or more solidified droplets.

23. The method of claim 9, further comprising adding the freeze dried dopant to a melt of semiconductor material.

24. The method of claim 23, further comprising pulling a single crystal ingot from the melt.
